(19) United States
(12) Patent Application Publication
(10) Pub. No.: US 2023/0328960 A1
(43) Pub. Date: Oct. 12, 2023

(54) SEMICONDUCTOR DEVICE

(71) Applicant: SK hynix Inc., Gyeonggi-do (KR)

(72) Inventors: Eun Jeong KIM, Gyeonggi-do (KR); Ji Hoon Kim, Gyeonggi-do (KR); Hun Joo Lee, Gyeonggi-do (KR)

(21) Appl. No.: 17/954,117

(22) Filed: Sep. 27, 2022

(30) Foreign Application Priority Data
Apr. 11, 2022 (KR) 10-2022-0044630

(51) Int. Cl. H01L 27/108; G11C 5/06

(52) U.S. Cl. CPC H01L 27/10814; G11C 5/063; H01L 27/10897

(57) ABSTRACT

A semiconductor device includes a substrate having a cell area and a peripheral area, transistors in the peripheral area over the substrate, a lower interlayer insulating layer between the transistors, interconnections and a first spacer layer over the transistors and the lower interlayer insulating layer, an upper interlayer insulating layer over the interconnections and the first spacer layer. The first spacer layer is disposed between the interconnections, The first spacer layer includes a first lower spacer layer and a first upper spacer layer over the first lower spacer layer. The first lower spacer layer and the first upper spacer layer include silicon, boron, and nitrogen. A boron concentration of the first lower spacer layer is different from a boron concentration of the first upper spacer layer.

### CROSS-REFERENCE TO RELATED APPLICATIONS

The present application claims priority of Korean Patent Application No. 10-2022-0044630, filed on Apr. 11, 2022, which is incorporated herein by reference in its entirety.

### BACKGROUND

### 1. Field

The present disclosure relates to semiconductor devices including spacer layers with a low-k dielectric material which has a dielectric constant lower than a dielectric constant of silicon nitride (SiN) and methods of manufacturing the semiconductor devices.

### 2. Description of the Related Art

As the degree of integration of semiconductor devices increases, signal delay and signal loss due to parasitic capacitance between conductive interconnection patterns are gradually emerging as issues to be addressed.

### SUMMARY

Embodiments of the disclosure provide semiconductor devices with reduced signal delay and signal loss.

Embodiments of the disclosure provide spacer layers having a low-k dielectric material which has a dielectric constant lower than a dielectric constant of silicon nitride between conductive interconnection patterns.

Embodiments of the disclosure provide methods of manufacturing spacer layers having a low-k dielectric material.

Embodiments of the disclosure provide methods of manufacturing semiconductor devices having spacer layers having a low-k dielectric material.

A semiconductor device in accordance with one embodiment of the disclosure includes a substrate having a cell area and a peripheral area, transistors in the peripheral area over the substrate, a lower interlayer insulating layer between the transistors, interconnections and a first spacer layer over the transistors and the lower interlayer insulating layer, an upper interlayer insulating layer over the interconnections and the first spacer layer. The first spacer layer is disposed between the interconnections. The first spacer layer includes a first lower spacer layer and a first upper spacer layer over the first lower spacer layer. The first lower spacer layer and the first upper spacer layer include elements of silicon, boron, and nitrogen. A boron concentration of the first lower spacer layer is different from a boron concentration of the first upper spacer layer.

A semiconductor device in accordance with an embodiment of the disclosure includes a substrate, transistors over the substrate, a lower interlayer insulating layer between the transistors, interconnections and a first spacer layer over the transistors and the lower interlayer insulating layers, and an upper interlayer insulating layer over the interconnections and the first spacer layer. The first spacers are disposed between the interconnections. The first spacer layer includes elements of silicon, boron, and nitrogen. The first spacer layer has a concentration gradient between a first region having a higher boron concentration and a second region having a lower boron concentration.

A semiconductor device in accordance with another embodiment of the present disclosure includes a substrate having a cell area and a peripheral area, transistors in the peripheral area over the substrate, a lower interlayer insulating layer between the transistors, interconnections and a first spacer layer over the transistors and the lower interlayer insulating layer, and an upper interlayer insulating layer over the interconnections and the first spacer layer. The first spacer layer is disposed between the interconnections. The first spacer layer includes a first silicon carbon oxide dielectric. The first spacer has an air gap.

A method of manufacturing a semiconductor device in accordance with still another embodiment of the disclosure includes preparing a substrate having a cell area and a peripheral area, forming transistors in the peripheral area over the substrate, forming interconnections and a first spacer layer over the transistors, and forming a via plug over one of the interconnections. Forming the first spacer layer includes forming an interconnection separation recess, performing a first spacer layer forming process to form a first lower spacer layer in the interconnection separation recess, and performing a second spacer layer forming process to form a first upper spacer layer over the first lower spacer layer. The first spacer layer forming process includes performing a first deposition process to form a boron nitride layer n2 times and performing a second deposition process to form a silicon nitride layer m1 times. The second spacer forming process includes performing a third deposition process to form a boron nitride layer n2 time and performing a fourth deposition process to form a silicon nitride layer m2 times, where the n1, n2, m1, and m2 are natural numbers. The is greater than the n2/m2.

A method of manufacturing a semiconductor device in accordance with yet another embodiment of the disclosure includes preparing a substrate; forming bit line structures over the substrate, forming landing pads and spacer layers over the bit line structures, and forming storage electrodes over the landing pads. Forming the spacer layer includes forming a node separation recess between the landing pads; and forming the spacer layer in the node separation recess. The spacer layer has a concentration gradient between a first region having a higher boron concentration and a second region having a lower boron concentration.

A method of manufacturing a semiconductor device accordance with one embodiment of the disclosure includes preparing a substrate, forming transistors over the substrate, forming interconnections and a spacer layer over the transistors, forming an etch stop layer over the interconnections and the spacer layer, and forming a via plug vertically passing through the etch stop layer to be connected to one of the interconnections. Forming the spacer layer includes forming an interconnection separation recess between the interconnections, and partially filling the interconnection separation recess with silicon carbon oxide dielectric to have an air gap in the interconnection separation recess.

A semiconductor device in accordance with another embodiment of the present disclosure includes a substrate having a cell area and a peripheral area; transistors in the peripheral area over the substrate; a lower interlayer insulating layer between the transistors; interconnections and a first spacer layer over the transistors and the lower interlayer insulating layer, wherein the first spacer layer is disposed between the interconnections; and an upper interlayer insulating layer over the interconnections and the first spacer layer. The first spacer layer includes a first low-k dielectric material having a) a dielectric constant lower than silicon nitride and b) a graded composition across a thickness of the first spacer layer.

### BRIEF DESCRIPTION OF THE DRAWINGS

FIGS. 1A to 2B are longitudinal cross-sectional views schematically illustrating semiconductor devices in accordance with various embodiments of the disclosure.

FIGS. 3 to 17 are views illustrating a method of manufacturing a semiconductor device in accordance with one embodiment of the present disclosure.

FIG. 18 is a view for describing a method of manufacturing a semiconductor device in accordance with another embodiment of the present disclosure.

FIG. 19 is a view for describing a method of manufacturing a semiconductor device in accordance with still another embodiment of the present disclosure.

FIG. 20 is a view for describing a method of manufacturing a semiconductor device in accordance with yet another embodiment of the present disclosure.

### DETAILED DESCRIPTION

Embodiments of the present invention will be described below in more detail with reference to the accompanying drawings. The present invention may, however, be embodied in different forms and should not be construed as limited to the embodiments set forth herein. Rather, these embodiments are provided so that this disclosure will convey the scope of the present invention to those skilled in the art. Throughout the disclosure, like reference numerals refer to like parts throughout the various figures and embodiments of the present invention.

It will be understood that, although the terms “first” and/or “second” may be used herein to describe various elements, these elements should not be limited by these terms. These terms are only used to distinguish one element, from another element. For instance, a first element discussed below could be termed a second element without departing from the teachings of the present disclosure. Similarly, the second element could also be termed the first element.

Other expressions that explain the relationship between elements, such as “between”, “directly between”, “adjacent to” or “directly adjacent to” should be construed in the same way.

The drawings are not necessarily to scale, and in some instances, proportions may have been exaggerated in order to clearly illustrate features of the embodiments. When a first layer is referred to as being “on” a second layer or “on” a substrate, it not only refers to a case where the first layer is formed directly over the second layer or the substrate but also a case where a third layer exists between the first layer and the second layer or the substrate.

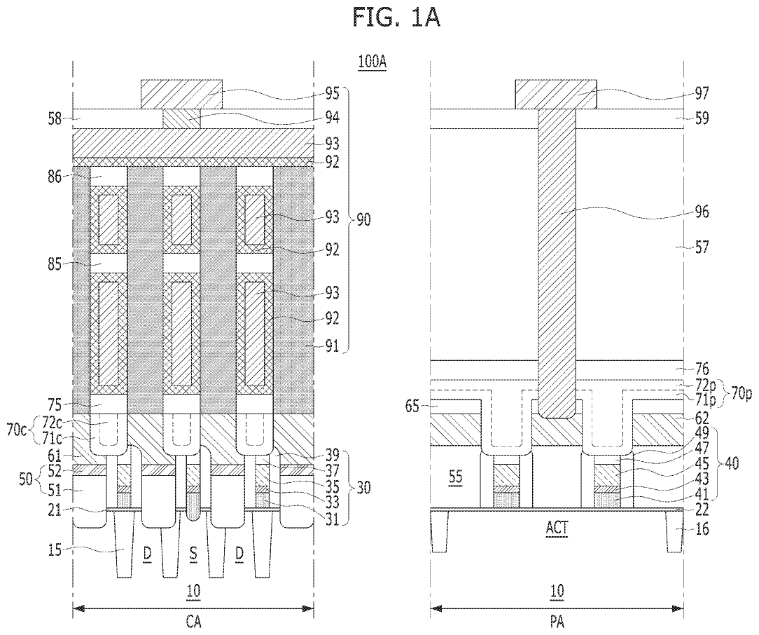

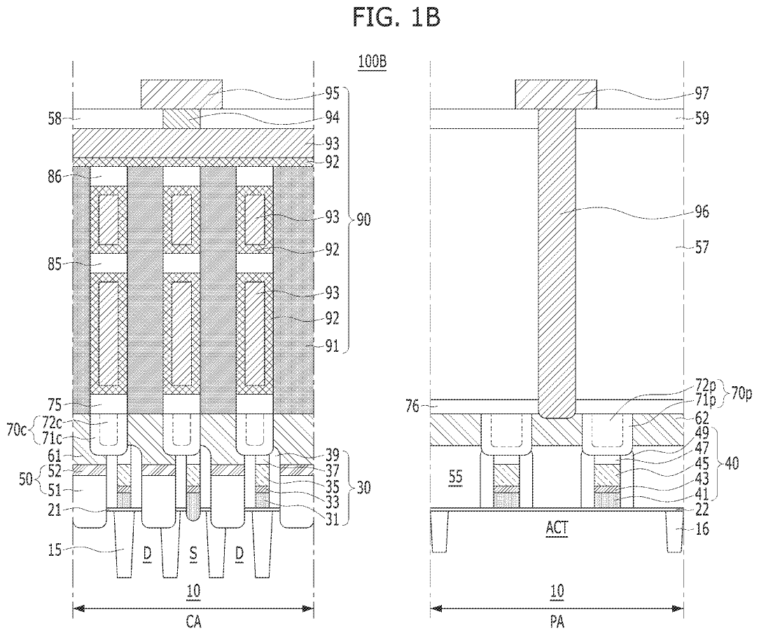

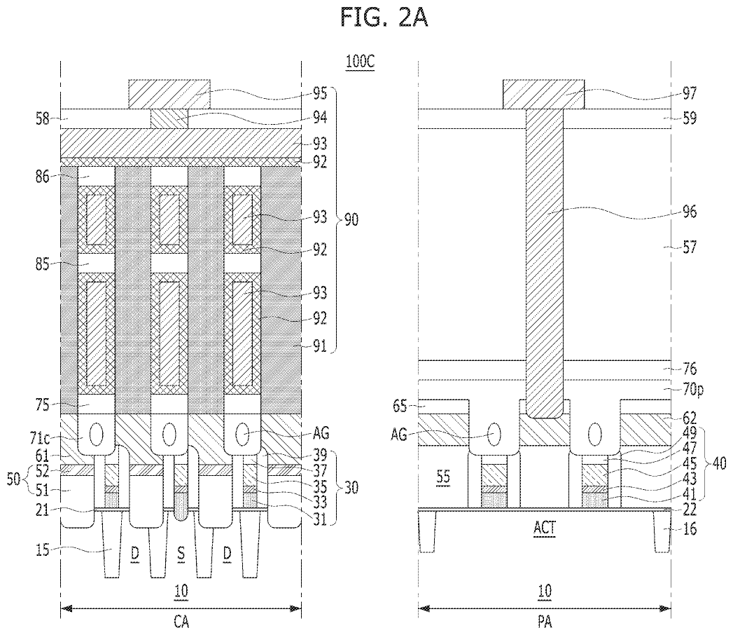

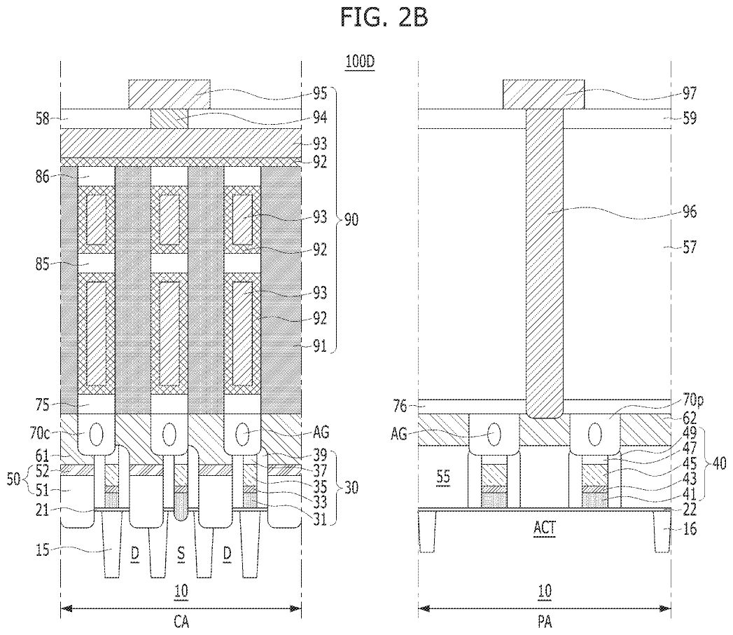

FIGS. 1A to 2B are longitudinal cross-sectional views schematically illustrating semiconductor devices 100A-100D in accordance with various embodiments of the disclosure. Referring to FIG. 1A, a semiconductor device 100A in accordance with one embodiment of the disclosure may include cell isolation regions 15, a cell surface insulating layer 21, bit line structures 30, storage contacts 50, landing pads 61, a cell spacer layer 70c, a cell etch stop layer 75, storage structures 90, supporting patterns 85 and 86, and a cell capping insulating layer 58 disposed in a cell area CA of a substrate 10, and peripheral isolation regions 16, a peripheral gate insulating layer 22, peripheral transistors 40, a lower interlayer insulating layer 55, peripheral interconnections 62, a peripheral spacer layer 70p, hard mask patterns 65, a peripheral etch stop layer 76, an upper interlayer insulating layer 57, a peripheral capping insulating layer 59, a peripheral via plug 96, and a peripheral interconnection pattern 97 disposed in a peripheral area PA of the substrate 10.

The cell isolation regions 15 may define source regions S and drain regions D in the cell area CA. The cell isolation regions 15 may include an insulating material filled in cell isolation trenches.

The cell surface insulating layer 21 may be conformally formed over a surface of the substrate 10 in the cell area CA. The cell surface insulating layer 21 may include at least one of silicon oxide (SiO₂), silicon nitride (SiN), or metal oxide.

Each of the bit line structures 30 may include a bit line contact 31, a bit line barrier layer 33, a bit line electrode 35, a bit line capping layer 37, and a bit line spacer 39. Side surfaces of the bit line contact 31, the bit line barrier layer 33, the bit line electrode 35, and the bit line capping layer 37 may be vertically aligned. The bit line spacer 39 may be formed over the side surfaces of the bit line contact 31, the bit line barrier layer 33, the bit line electrode 35, and the bit line capping layer 37. The bit line contact 31 may include a conductor such as one of an N-type doped silicon, a metal silicide, a metal compound, a metal alloy, and a metal. The bit line contact 31 vertically aligned with the source region S may downwardly protrude into the source region S of the substrate 10 (as depicted in the center bit line contact in FIG. 1A). That is, the source region S and the bit line contact 31 may he electrically connected with each other. The bit line barrier layer 33 may include a metal silicide or a harrier material e.g., titanium nitride (TiN). The bit line electrode 35 may include a metal e.g., tungsten (W). The bit line capping layer 37 and the bit line spacer 39 may include an insulating material e.g., silicon nitride (SiN).

The storage contacts 50 may be formed between the bit line structures 30 to be electrically connected to the drain regions D. The storage contacts 50 may include a lower storage contact 51 and an upper storage contact 52. The lower storage contact 51 may include an N-type doped silicon or a metal silicide. The upper storage contact 52 may include a metal silicide or a barrier metal.

The landing pads 61 may be formed over the storage contacts 50 to extend onto the bit line structures 30. The landing pads 61 may be electrically connected to the storage contacts 50, respectively. The landing pads 61 may include a metal compound e.g., titanium nitride (TiN) or a metal e.g., tungsten (W). The landing pads 61 may have an offset pillar shape.

The cell spacer layer 70c may be a low-K dielectric material formed between the landing pads 61 to electrically insulate the landing pads 61. The cell spacer layer 70c may include multi-layered insulating layers. For example, the cell spacer layer 70c may include a lower cell spacer layer 71c and an upper cell spacer layer 72c. The upper cell spacer layer 72c may be formed over the lower cell spacer layer 71c. For example, the lower cell spacer layer 71c may have a U-shaped cross-section (as depicted in FIGS. 1A and 1B) that surrounds a bottom surface and side surfaces of the upper cell spacer layer 72c. The lower cell spacer layer 71c may include silicon boron nitride (SiBN) having a first boron (B) concentration, and the upper cell spacer layer 72c may include silicon boron nitride (SiBN) having a second boron (B) concentration. The first boron (B) concentration may be higher than the second boron (B) concentration. A boron concentration gradient may be formed between the lower cell spacer layer 71c and the upper cell spacer layer 72c, For example, the boron (B) concentration in the cell spacer layer 70c may gradually decrease from the lower cell spacer layer 71c to the upper cell spacer layer 72c. An interface between the lower cell spacer layer 71c and the upper cell spacer layer 72c may virtually exist. Accordingly, the cell spacer layer 70c may have a first region 71c (an outer region or a lower region) having a relatively high boron concentration and a second region 72c (a central region or an upper region) having a relatively low boron concentration.

In one embodiment, the upper cell spacer layer 72c may further include carbon (C). For example, the lower cell spacer layer 71c may include silicon boron nitride (SiBN), and the upper cell spacer layer 72c may include silicon boron carbon nitride (SiBCN). In another embodiment, the lower cell spacer layer 71c may further include carbon (C). The lower cell spacer layer 71c may have a relatively low first carbon concentration, and the upper cell spacer layer 72c may have a relatively high second carbon concentration. Accordingly, the cell spacer layer 70c may have a carbon concentration gradient between the lower cell spacer layer 71c and the upper cell spacer layer 72c.

In the example of the lower cell spacer layer 71c having a higher boron concentration or a lower carbon concentration than the upper spacer layer 72c, the lower cell spacer layer 71c may have a lower dielectric constant than the upper cell spacer layer 72c. In the example of the upper cell spacer layer 72c having a lower boron concentration or a higher carbon concentration than the lower cell spacer layer 71c, the upper cell spacer layer 72c may have an etching resistance higher than an etching resistance of the lower cell spacer layer 71c. Although the cell spacer layer 70c is illustrated as including two cell spacer layers 71c and 72c, the cell spacer layer 70c may include three or more cell spacer layers.

The cell etch stop layer 75 may be formed over the cell spacer layer 70c to be vertically aligned with the cell spacer layer 70c. The cell etch stop layer 75 may have an etch selectivity with respect to the cell spacer layer 70c. For example, the cell etch stop layer 75 may include silicon nitride (SiN).

Each of the storage structures 90 may include a storage electrode 91, a storage dielectric layer 92, a plate electrode 93, a plate contact pattern 94, and a plate interconnection pattern 95. The storage electrodes 91 may be formed over the landing pads 61 to be vertically aligned with the landing pad 61, respectively. The storage electrodes 91 may have a vertical pillar shape, The storage electrodes 91 may include a metal compound e.g., titanium nitride (TiN) or a metal e.g., tungsten (W). The storage electrodes 91 may be electrically insulated from each other.

The supporting patterns 85 and 86 may form a lower supporting pattern 85 and an upper supporting pattern 86. The lower supporting pattern 85 and the upper supporting pattern 86 may surround side surfaces of the storage electrodes 91. Accordingly, the lower supporting pattern 85 may fix and support middle portions of the storage electrodes 91, and the upper supporting pattern 86 may fix and support upper portions of the storage electrodes 91 so that the storage electrodes 91 do not collapse. The supporting patterns 85 and 86 may include an insulating material e.g., silicon nitride (SiN).

The storage dielectric layer 92 may be conformally formed over surfaces of the storage electrodes 91 and surfaces of the supporting patterns 85 and 86. The storage dielectric layer 92 may include an insulating material e.g., metal oxide.

The plate electrode 93 may cover the storage dielectric layer 92. The plate electrode 93 may include a metal nitride e.g., titanium nitride (TiN) or a metal. The plate electrodes 93 may be connected as a whole without being separated from each other.

The cell capping insulating layer 58 may be formed over the plate electrode 93, and the plate interconnection pattern 95 may be formed over the cell capping insulating layer 58. The plate contact pattern 94 may vertically pass through the cell capping insulating layer 58 to electrically connect the plate electrode 93 to the plate interconnection pattern 95. The cell capping insulating layer 58 may include an insulating material e.g., silicon nitride (SiN). The plate contact pattern 94 and the plate interconnection pattern 95 may include a metal compound or a metal.

The peripheral isolation regions 16 may define peripheral active regions ACT of the peripheral transistors 40 in the peripheral area PA. The peripheral isolation regions 16 may include an insulating material filled in the perimeter isolation trenches.

The peripheral gate insulating layer 22 may be conformally formed over the surface of the substrate 10 in the peripheral area PA. The peripheral gate insulating layer 22 may include at least one of silicon oxide (SiO₂), silicon nitride (SiN), or a metal oxide.

Each of the peripheral transistors 40 may include a lower gate electrode 41, an intermediate gate electrode 43, an upper gate electrode 45, a gate capping layer 47, and a gate spacer 49. The lower gate electrode 41, the intermediate gate electrode 43, the upper gate electrode 45, and the gate capping layer 47 may be stacked so that side surfaces thereof are vertically aligned. The gate spacer 49 may be formed over the side surfaces of the lower gate electrode 41, the intermediate gate electrode 43, the upper gate electrode 45, and the gate capping layer 47. The bit line structures 30 and the peripheral transistors 40 may be formed at the same level.

The lower interlayer insulating layer 55 may fill spaces between the peripheral transistors 40. The lower interlayer insulating layer 55 may be also formed in the cell area CA. In the cell area CA, the lower interlayer insulating layer 55 may be formed between the bit line structures 30 and the storage contacts 50.

The peripheral interconnections 62 may include a metal compound e.g., titanium nitride (TiN) or a metal e.g., tungsten (W). The peripheral interconnections 62 may be formed in a shape of lines extending in parallel with each other. The peripheral interconnections 62 may be formed at the same level as the landing pads 61 of the cell area CA.

The hard mask pattern 65 may be formed over the peripheral interconnections 62. The hard mask pattern 65 may have an etch selectivity with respect to the peripheral spacer layer 70p. For example, the hard mask pattern 65 may include silicon nitride (SiN).

The peripheral spacer layer 70p may be a low-K dielectric material formed between the peripheral interconnections 62 to electrically insulate the peripheral interconnections 62. The peripheral spacer layer 70p may extend onto the hard mask pattern 65. The peripheral spacer layer 70p may be formed at the same level as the cell spacer layer 70c. The peripheral spacer layer 70p and the cell spacer layer 70c may be formed at the same level as the peripheral interconnections 2 and the landing pads 61. The peripheral spacer layer 70p may include multi-layered insulating layers. For example, the peripheral spacer layer 70p may include a lower peripheral spacer layer 71p and an upper peripheral spacer layer 72p. The lower peripheral spacer layer 71p may have a U-shaped cross-section (as depicted in FIGS. 1A and 1B) surrounding a bottom surface and side surfaces of the upper peripheral spacer layer 72p, The lower peripheral spacer layer 71p may include silicon boron nitride (SiBN) having a first boron concentration, and the upper peripheral spacer layer 72p may include silicon boron nitride (SiBN) having a second boron concentration. The first boron concentration may be higher than the second boron concentration. A boron concentration gradient may be formed between the lower peripheral spacer layer 71p and the upper peripheral spacer layer 72p. For example, the boron concentration gradient in the peripheral spacer layer 70p may be gradually lowered from the lower peripheral spacer layer 71p to the upper peripheral spacer layer 72p. An interface between the lower peripheral spacer layer 71p and the upper peripheral spacer layer 72p may virtually exist. Accordingly, the peripheral spacer layer 70p has a first region 71p (outer region or lower region) having a relatively high boron concentration and a second region 72p (central region or the upper region) having a relatively low boron concentration.

In another embodiment, the upper peripheral spacer layer 72p may further include carbon (C). For example, the lower peripheral spacer layer 71p may include silicon boron nitride (SiBN), and the upper peripheral spacer layer 72p may include silicon boron carbon nitride (SiBCN). In another embodiment, the lower peripheral spacer layer 71p may further include carbon (C). The lower peripheral spacer layer 71p may have a relatively low first carbon concentration, and the upper peripheral spacer layer 72c may have a relatively high second carbon concentration. Accordingly, the peripheral spacer layer 70p may have a carbon concentration gradient.

In the example of the lower peripheral spacer layer 71p having a higher boron concentration or a lower carbon concentration than the upper peripheral spacer layer 72p, the lower peripheral spacer layer 71p may have a lower dielectric constant than the upper peripheral spacer layer 72p. In the example of the upper peripheral spacer layer 72p having a lower boron concentration or a higher carbon concentration than the lower peripheral spacer layer 71p, the upper peripheral spacer layer 72p may have an etching resistance higher than the lower peripheral spacer layer 71p. Although the peripheral spacer layer 70p is shown having two layers of peripheral spacer layers 71p and 72p, the peripheral spacer layer 70p may include three or more peripheral spacer layers.

The peripheral etch stop layer 76 may be formed over the peripheral spacer layer 70p. The peripheral etch stop layer 76 may have an etch selectivity with respect to the peripheral spacer layer 70p and the upper interlayer insulating layer 57. For example, the peripheral etch stop layer 76 may include an insulating material e.g., silicon nitride (SiN).

The upper interlayer insulating layer 57 may be formed over the peripheral etch stop layer 76. The upper interlayer insulating layer 57 may include an insulating material e.g., silicon oxide (SiO₂).

The peripheral capping insulating layer 59 may be formed over the upper interlayer insulating layer 57, The peripheral capping insulating layer 59 may have an etch selectivity with respect to the upper interlayer insulating layer 57. The peripheral capping insulating layer 59 may include an insulating material e.g., silicon nitride (SiN).

The peripheral interconnection pattern 97 may be formed over the peripheral capping insulating layer 59, The peripheral interconnection pattern 97 may include a metal compound or a metal.

The peripheral via plug 96 may vertically pass through the peripheral capping insulating layer 58, the upper interlayer insulating layer 57, and the peripheral etch stop layer 76 to electrically connect the peripheral interconnection pattern 97 to the peripheral interconnections 62

Referring to FIG. 1B, a semiconductor device 100B in accordance with another embodiment of the present disclosure, the hard mask pattern 65 in the peripheral area PA may be omitted and a portion of the peripheral spacer layer 70p may not be formed over the peripheral interconnections 62 as compared to the semiconductor device 100A shown in FIG. 1A. That is, the peripheral spacer layer 70p may be formed only between the peripheral interconnections 62. Other elements not described can be understood with reference to FIG. 1A.

Referring to FIG. 2A, a semiconductor device 100C in accordance with still another embodiment of the present disclosure may have a cell spacer layer 70c and a peripheral spacer layer 70p including an air gap AG, respectively, as compared to the semiconductor device 100A shown in FIG. 1A. The cell spacer layer 71c and the peripheral spacer layer 70p may include silicon carbon oxide (SiCO). Other elements not described can be understood with reference to FIGS. 1A and 1B.

Referring to FIG. 2B, a semiconductor device 100D in accordance with yet another embodiment of the present disclosure may not include the hard mask pattern 65 in the peripheral area PA and the peripheral spacer layer 70p over the peripheral interconnections 62 as compared to the semiconductor device 100C illustrated in FIG. 2A. That is, the hard mask pattern 65 may be omitted in the peripheral area PA, and the peripheral spacer layer 70p may be formed only between the peripheral interconnections 62. Other elements not described can be understood with reference to FIGS. 1A, 1B, and 2A.

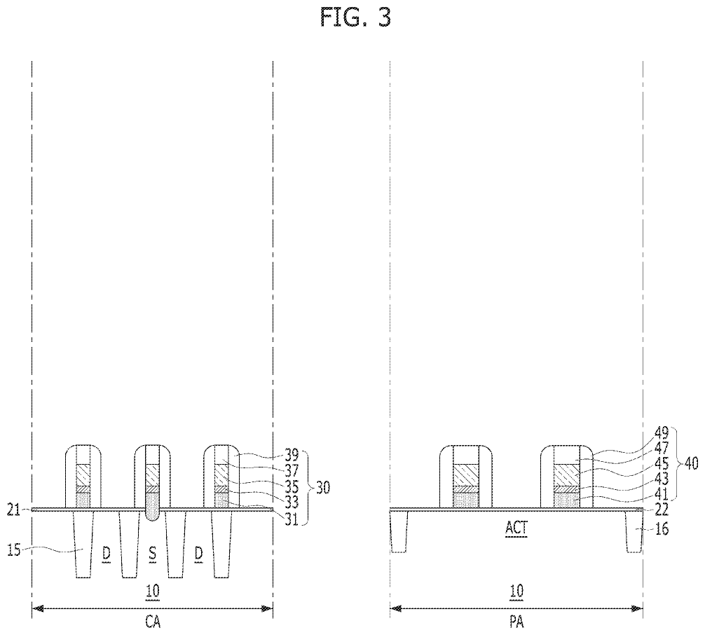

FIGS. 3 to 17 are views illustrating a method of manufacturing a semiconductor device in accordance with another embodiment of the present disclosure. Referring to FIG. 3, the method may include preparing a substrate 10 having a cell area CA and a peripheral area PA, forming isolation regions 15 and 16 in the substrate 10, forming insulating layers 21 and 22 over the substrate 10, forming bit line structures 30 in the cell area CA, and forming peripheral transistors 40 in the peripheral area PA.

The substrate 10 may include a semiconducting layer e.g., a single crystalline silicon wafer, a silicon-on-insulator (SOI), an epitaxial grown layer, or a compound semiconductor. The isolation regions 15 and 16 may be cell isolation regions 15 in the cell area CA and peripheral isolation regions 16 in the peripheral area PA. The cell isolation regions 15 may define a source region S and drain regions D, and the peripheral isolation regions 16 may define a peripheral active region ACT. The isolation regions 15 and 16 may be formed by forming trenches in the substrate 10 and filling the trenches with an insulating material e.g., silicon oxide (SiO₂) or silicon nitride (SiN).

The insulating layers 21 and 22 may include a cell surface insulating layer 21 formed over the substrate 10 in the cell area CA and a peripheral gate insulating layer 22 formed over the substrate 10 in the peripheral area PA. The insulating layers 21 and 22 may include at least one of a silicon oxide (SiO₂) layer, a silicon nitride (SiN) layer, a metal oxide layer, or other various insulating material layers formed through an oxidation process or a deposition process.

Each of the bit line structures 30 may include a bit line contact 31, a bit line barrier layer 33, a bit line electrode 35, a bit line capping layer 37, and a bit line spacer 39. Forming the bit line structures 30 may include a) forming a bit line contact material layer, a bit line barrier material layer, a bit line electrode material layer, and a bit line capping material layer over the cell surface insulating layer 21, b) performing a patterning process to form a bit line contact 31, a bit line barrier layer 33, a bit line electrode 35, and a bit line capping layer 37, c) forming a bit line spacer material layer, and d) performing an etch-back process to form a bit line spacers 39. Accordingly, in one embodiment, the bit line contact 31, the bit line barrier layer 33, the bit line electrode 35, and the bit line capping layer 37 may be stacked so that side surfaces thereof are vertically aligned. The bit line spacer 39 may be formed over the side surfaces of the bit line contact 31, the bit line barrier layer 33, the bit line electrode 35, and the bit line capping layer 37. The bit line spacer may be formed by forming the bit line spacer material covering the bit line contact 31, the bit line barrier layer 33, the bit line electrode 35, and the bit line capping layer 37, and thereafter patterning the bit line spacer material by performing the etch-back process.

The bit line contact 31 may include an N-type doped silicon layer or a metal silicide. The bit line contact 31 vertically aligned with the source region S may be formed to protrude downwardly into the source region S of the substrate 10, The bit line barrier layer 33 may include a metal silicide layer or a barrier metal layer. The bit line electrode 35 may include a metal e.g., tungsten (W). The bit line capping layer 37 and the bit line spacer 39 may include an insulating material e.g., silicon nitride.

Each of the peripheral transistors 40 may include a lower gate electrode 41, an intermediate gate electrode 43, an upper gate electrode 45, a gate capping layer 47, and a gate spacer 49. Forming the peripheral transistors 40 may include a) forming a lower gate electrode material layer, an intermediate gate electrode material layer, an upper gate electrode material layer, and a gate capping material layer over the peripheral gate insulating layer 22, and b) performing a patterning process to form the lower gate electrode 41, the intermediate gate electrode 43, the upper gate electrode 45, and the gate capping layer 47, c) forming the gate spacer material layer, and d) performing an etch-back process to form the gate spacer 49. Accordingly, in one embodiment, the lower gate electrode 41, the middle gate electrode 43, the upper gate electrode 45, and the gate capping layer 47 may be stacked so that side surfaces thereof are vertically aligned. The gate spacer 49 may be formed over the side surfaces of the lower gate electrode 41, the middle gate electrode 43, the upper gate electrode 45, and the gate capping layer 47.

The bit line contact 31 and the lower gate electrode 41 may include the same material, the bit line barrier layer 33 and the intermediate gate electrode 43 may include the same material, the bit line electrode 35 and the upper gate electrode 45 may include the same material, the bit line capping layer 37 and the gate capping layer 47 may include the same material, and the bit line spacer 39 and the gate spacer 49 may include the same material. In one embodiment, the bit line structures 30 and the peripheral transistors 40 may be formed by the same processes at the same time.

In one embodiment, cell gate structures buried in the substrate 10 may be further formed in the cell area CA.

The semiconductor device in accordance with one embodiment may be a DRAM device having a buried channel array to satisfy the 6F² design rule.

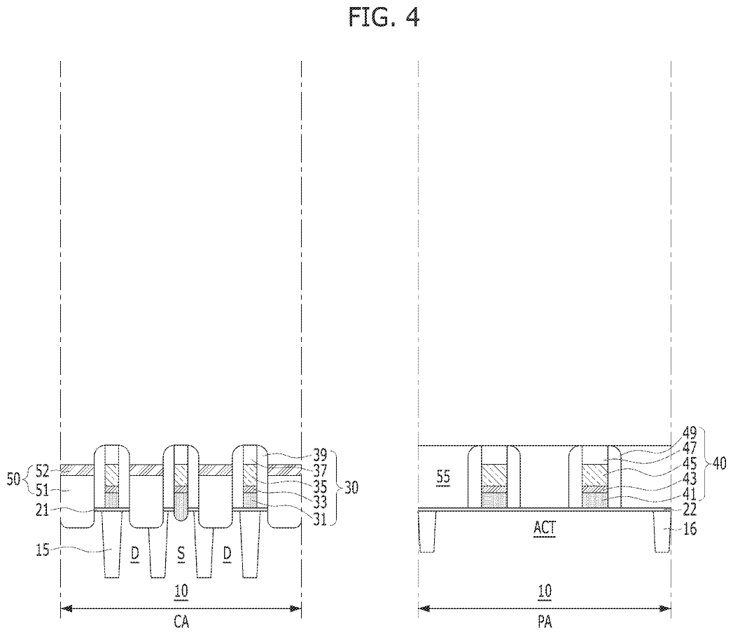

Referring to FIG. 4, the method may further include forming storage contacts 50 in the cell area CA and forming a lower interlayer insulating layer 55 in the peripheral area PA. Each of the storage contacts 50 may be formed to protrude downwardly into the drain region D of the substrate 10. The storage contacts 50 may be vertically aligned with and electrically connected to the drain region D. Each of the storage contacts 50 may include a lower storage contact 51 and an upper storage contact 52. The lower storage contact 51 may include an N-type doped silicon layer or a metal silicide layer. The upper storage contact 52 may include a metal silicide layer or a barrier metal layer. The lower interlayer insulating layer 55 may include a silicon oxide (SiO₂) layer or a silicon nitride (SiN) layer. The lower interlayer insulating layer 55 may also be formed in the cell area CA.

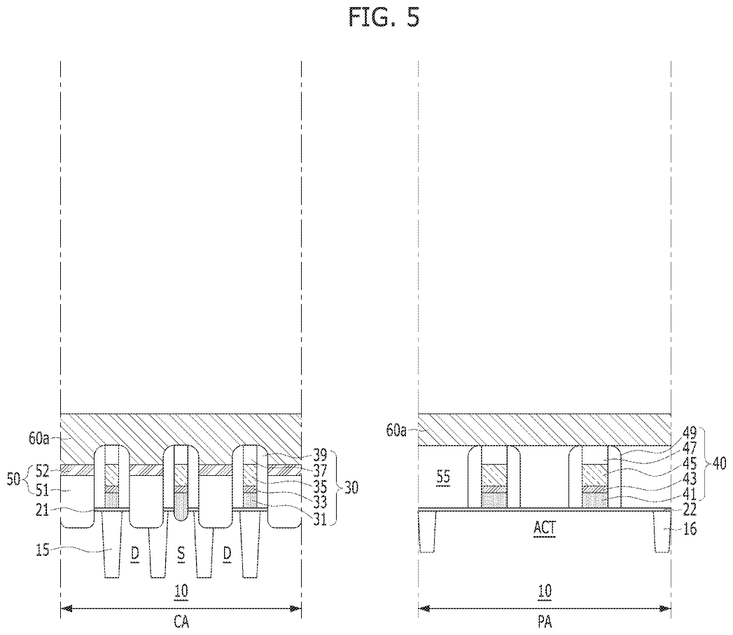

Referring to FIG. 5, the method may further include entirely forming a conductive material layer 60a. The conductive material layer 60a may include a metal compound e.g., titanium nitride (TiN) or a metal e.g., tungsten (W). The conductive material layer 60a may be electrically connected to the storage contacts 50 in the cell area CA.

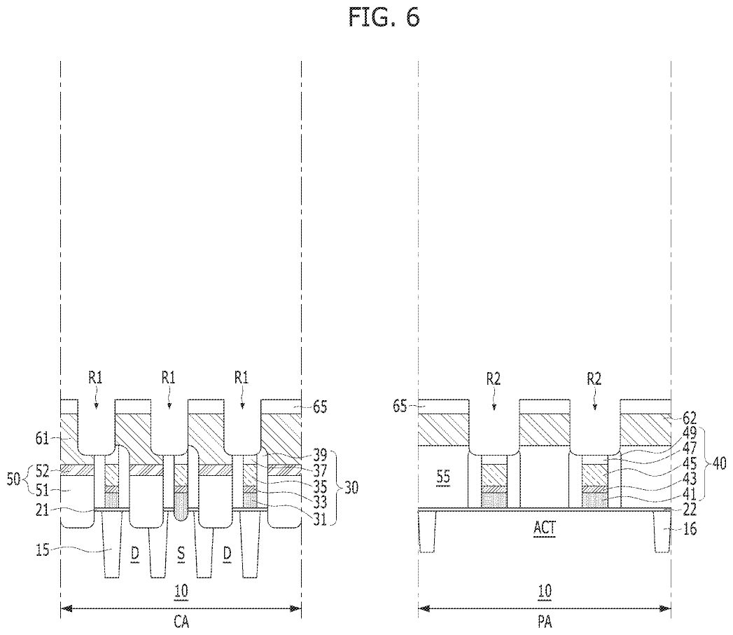

Referring to FIG. 6, the method further includes forming a hard mask pattern 65 over the conductive material layer 60a, and forming recesses R1 and R2 to form a plurality of conductive patterns 61 and 62 from the conductive material layer 60a. The recesses R1 and R2 may include a plurality of node separation recesses R1 in the cell area CA and a plurality of interconnection separation recesses R2 in the peripheral area PA. In the cell area CA, the conductive material layer 60a may be transformed into the plurality of landing pads 61 by the node separation recesses R1. In the peripheral area PA, the conductive material layer 60a may be formed into a plurality of conductive peripheral interconnections 62 by the plurality of interconnection separation recesses R2.

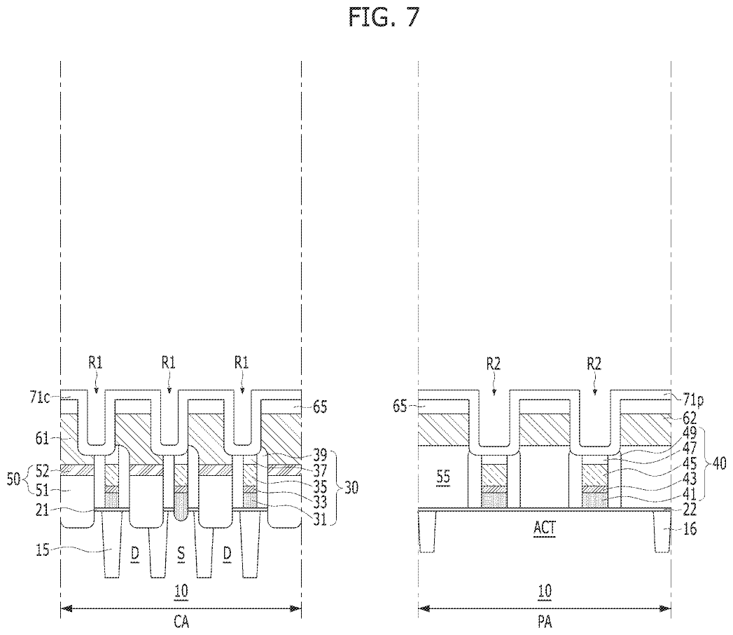

Referring to FIG. 7, the method may further include performing a lower spacer layer forming process to conformally form lower spacer layers 71c and 71p over inner walls and bottom surfaces of the recesses R1 and R2. The lower spacer layers 71c and 71p may include a silicon boron nitride (SiBN) layer. For example, the lower spacer layer forming process may include performing a first deposition process n1 times to form a boron nitride (BN) layer, and performing a second deposition process m1 times to form a silicon nitride (SiN) layer. (Where the n1 and m1 are natural numbers.) The first deposition process may include purging an inside of a deposition chamber, supplying a gas containing the element boron (B), e.g., BCl₃, into the deposition chamber to form a boron (B) layer over the wafer, purging the inside of the deposition chamber again, and supplying a gas containing the element nitrogen (N), e.g., NH₃, into the deposition chamber to form a boron nitride (BN) layer from the boron (B) layer, in succession. The second deposition process may include purging the inside of the deposition chamber, supplying a gas containing the element silicon (Si), e.g., SiH₂Cl₂, into the deposition chamber to form a silicon (Si) layer over the boron nitride (BN) layer, purging the inside of the deposition chamber again, and supplying a gas containing the element nitrogen (N), e.g., NH₃, into the deposition chamber to form a silicon nitride (SiN) layer from the silicon (Si) layer, in succession. The boron (B) of the boron nitride (BN) layer may diffuse into the silicon nitride (SiN) layer and the silicon (Si) of the silicon nitride (SiN) layer may diffuse into the boron nitride (BN) layer. Thus, a silicon boron nitride (SiBN) layer may be formed by the lower spacer layer forming process.

The first deposition process and the second deposition process may be repeatedly performed, respectively. Alternately, the first deposition process and the second deposition process may be alternately or repeatedly performed in combination. For example, the silicon boron nitride (SiBN) layer may be formed by repeatedly performing the first deposition process once and the second deposition process once. Alternatively, the silicon boron nitride (SiBN) layer may be repeatedly formed by performing the first deposition process twice and performing the second deposition process once. In another embodiment, the silicon boron nitride (SiBN) layer may be formed by repeatedly performing the first deposition process three times and performing the second deposition process twice. In another embodiment, a silicon boron nitride (SiBN) layer may be formed by performing the first deposition process, performing the second deposition process, and performing the first deposition process again.

A composition ratio of the silicon boron nitride (SiBN) layer may be adjusted by repetition times of the first deposition process and repetition times of the second deposition process. For example, as the number of performing times of the first deposition process is greater than the number of performing times of the second deposition process, the boron (B) concentration of the silicon boron nitride (SiBN) layer can be higher. B-rich SiBN). In one embodiment, in order to increase the boron concentration, the number of performing times of the first deposition process may be greater than the performing times of the second deposition process. (n1>m1).

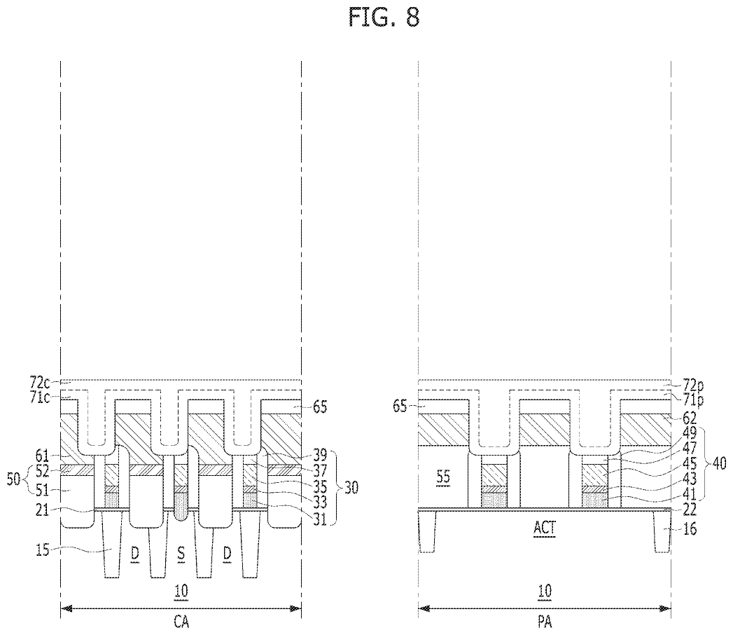

Referring to FIG. 8, the method may further include performing an upper spacer layer forming process to form upper spacer layers 72c and 72p over the lower spacer layers 71c and 71p. For example, the upper spacer layer 72p may fill inside the recesses R1 and R2. In one embodiment, the upper spacer layers 72c and 72p may also include a silicon boron nitride (SiBN) layer. The upper spacer layer forming process may include repeatedly performing a third deposition process n2 times to form a boron nitride (BN) layer and a fourth deposition process m2 times to form a silicon nitride (SiN) layer, where the n2 and m2 are natural numbers). The third deposition process may include purging the inside of the deposition chamber, supplying a gas containing the element boron (B), e.g., BCl₃, into the deposition chamber to form a boron (B) layer over the silicon boron nitride (SiBN) layer formed by the lower spacer layer forming process, purging the inside of the deposition chamber again, and supplying a gas containing the element nitrogen (N), e.g., NH₃, into the deposition chamber to form a boron nitride (BN) layer from the boron (B) layer, in succession. The fourth deposition process may include purging the inside of the deposition chamber, supplying a gas containing the element silicon (Si), e.g., SiH₂Cl2, into the deposition chamber to form a silicon (Si) layer over the boron nitride (BN) layer, purging the inside of the deposition chamber again, and supplying a gas containing the element nitrogen (N), e.g., NH₃, into the deposition chamber to form a silicon nitride (SiN) layer from the silicon (Si) layer, in succession. The boron (B) of the boron nitride (BN) layer may diffuse into the silicon nitride (SiN) layer and the silicon (Si) of the silicon nitride (SiN) layer may diffuse into the boron nitride (BN) layer. Thus, the silicon boron nitride (SiBN) layer may be formed by the upper spacer layer forming process.

The third deposition process and the fourth deposition process may be repeatedly performed, respectively. Alternatively, the third deposition process and the fourth deposition process may be alternately or repeatedly performed in combination. For example, the silicon boron nitride (SiBN) layer may be formed by repeatedly performing the third deposition process once and the fourth deposition process once. Alternatively, the silicon boron nitride (SiBN) layer may be repeatedly formed by performing the third deposition process twice and performing the fourth deposition process once.In another embodiment, the silicon boron nitride (SiBN) layer may be formed by repeatedly performing the third deposition process three times and performing the fourth deposition process twice. In another embodiment, a silicon boron nitride (SiBN) layer may be formed by performing the third deposition process, performing the fourth deposition process, and performing the third deposition process again.

A composition ratio of the silicon boron nitride (SiBN) layer may be adjusted by repetition times of the third deposition process and repetition times of the fourth deposition process. For example, as the number of performing times of the third deposition process is greater than the number of performing times of the fourth deposition process, the boron (B) concentration of the silicon boron nitride (SiBN) layer can be higher. (e.g., B-rich SiBN). In one embodiment, in order to increase the boron concentration, the number of performing times of the third deposition process may be greater than the number of performing times of the fourth deposition process (n2>m2).

The boron concentration of the upper spacer layers 72c and 72p may be lower than the boron concentration of the lower spacer layers 71c and 71p. (e.g. B-poor SiBN). For example, if it is assumed that the number of performing times of the second deposition process to form the lower spacer layers 71c and 71p is equal to the number of performing times of the fourth deposition process to form the upper spacer layers 72c and 72p, the number of performing times of the first deposition process to form the lower spacer layers 71c and 71p may be greater than the number of performing times of the third deposition process to form the upper spacer layers 72c and 72p. That is, if m1=m2, then n1>n2. Further, the number of performing times of the third deposition process to form the upper spacer layers 72c and 72p may be less than the number of performing times of the first deposition process to form the lower spacer layers 71c and 71p.

In one embodiment, the upper spacer layers 72c and 72p may further include carbon (C). For example, the upper spacer layers 72c and 72p may include silicon boron carbon nitride (SiBCN). Forming the silicon boron carbon nitride (SiBCN) layer may include repeatedly performing a third deposition process to form a boron nitride (BN) layer and a modified fourth deposition process to form a silicon carbon nitride (SiCN) layer. The modified fourth deposition process may include purging the inside of the deposition chamber, supplying a gas containing the element silicon (Si), e.g., SiH₂Cl₂, into the deposition chamber to form a silicon (Si) layer over the boron nitride (BN) layer, purging the inside of the deposition chamber again, supplying a gas containing the element carbon (C), e.g., C₂H₄, into the deposition chamber to form a silicon carbide (SiC) layer from the silicon (Si) layer, purging the inside of the deposition chamber again, and supplying a gas containing the element nitrogen (N), e.g., NH₃, into the deposition chamber to form a silicon carbon nitride (SiCN) layer from the silicon carbide (SiC) layer, in succession.

The dielectric constant of boron (B) is lower than the dielectric constant of nitrogen (N) and the dielectric constant of carbon (C). Accordingly, in the example of the lower spacer layers 71c and 71p having a higher boron concentration (or higher boron content) than the upper spacer layers 72c and 72p, the dielectric constants of the lower spacer layers 71c and 71p may be lower than the dielectric constants of the upper spacer layers 72c and 72p. The lower spacer layers 71c and 71p may have an etching resistance lower than an etching resistance of the upper spacer layers 72c and 72p. The boron concentration or the boron content of the silicon boron nitride (SiBN) layer can be adjusted to have a gradient. Accordingly, the optimal composition ratio of silicon boron nitride (SiBN) and the boron concentration gradient can be obtained to have low dielectric constant and high etching resistance.

In one embodiment, because the boron concentration of the lower spacer layers 71c and 71p is higher than the boron concentration of the upper spacer layers 72c and 72p, a ratio of the number of performing times of the deposition processes may be expressed as: n1/m1>n2/m2. That is, the process of forming the boron nitride (BN) layer of the process of forming the lower spacer layers 71c and 71p may be more performed more times than the process of forming the boron nitride (BN) layer of the process of forming the upper spacer layers 72c and 72p.

If the lower spacer layers 71C and 71P include the same materials, the interface between the lower spacer layers 71c and 71p and the upper spacer layers 72c and 72p may exist virtually. Thus, the interface between the lower spacer layers 71c and 71p and the upper spacer layers 72c and 72p is indicated by the dotted line shown in FIG. 8. As mentioned above, the spacer layers 70c and 70p may have a gradual concentration gradient of boron (B) or carbon (C) therein. For example, a concentration gradient of boron (B) or carbon (C) may be gradually formed between outer regions and central regions of the spacer layers 70c and 70p. In one embodiment, the characteristics of the lower spacer layers 71c and 71p and the characteristics of the upper spacer layers 72c and 72p may be exchanged.

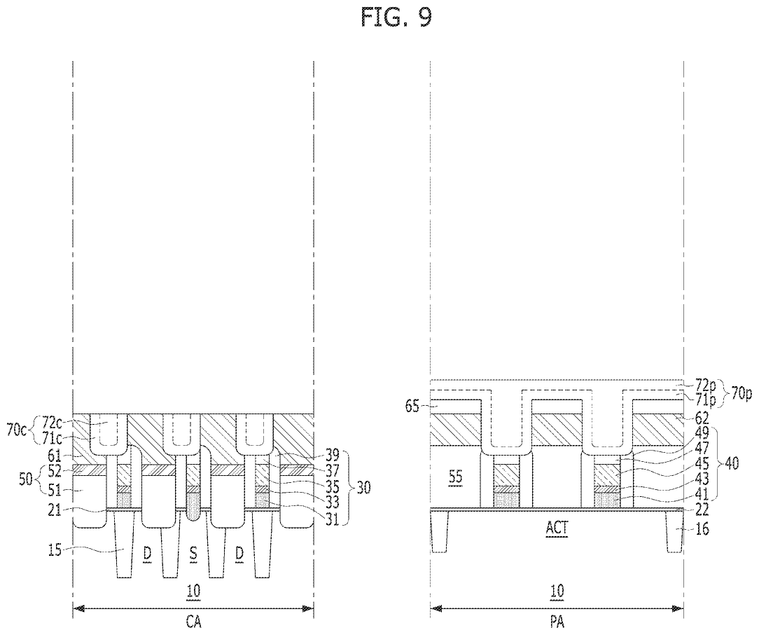

Referring to FIG. 9, the method may further include exposing the cell area CA, and exposing upper surfaces of the landing pads 61 by performing an etching process to remove the spacer layers 70c and 70p and the hard mask pattern 65 over upper surfaces of the landing pads 61. The peripheral area PA may be covered by a photoresist pattern or the like.

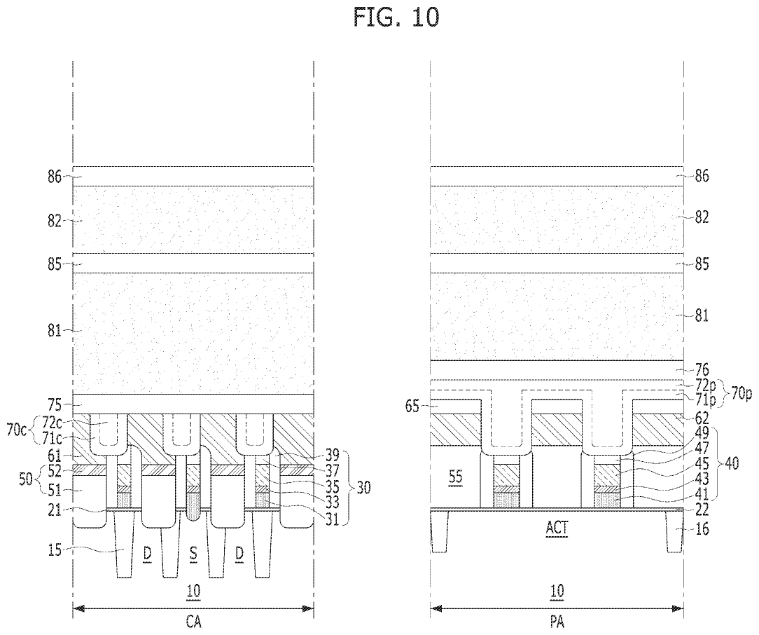

Referring to FIG. 10, the method may further include performing deposition processes to form etch stop layers 75 and 76, a lower mold insulating layer 81, a lower supporting pattern 85, an upper mold insulating layer 82, and an upper supporting pattern 86. The etch stop layers 75 and 76 may include a material layer having an etch selectivity with respect to silicon oxide (SiO₂), e.g., silicon nitride (SiN). The lower mold insulating layer 81 and the upper mold insulating layer 82 may include a material layer that can be removed, e.g., silicon oxide (SiO₂), more easily than the etch stop layers 75 and 76 and the supporting patterns 85 and 86. The lower supporting pattern 85 and the upper supporting pattern 86 may have an etch selectivity with respect to the lower mold insulating layer 81 and the upper mold insulating layer 82. For example, the lower supporting pattern 85 and the upper supporting pattern 86 may include silicon nitride (SiN).

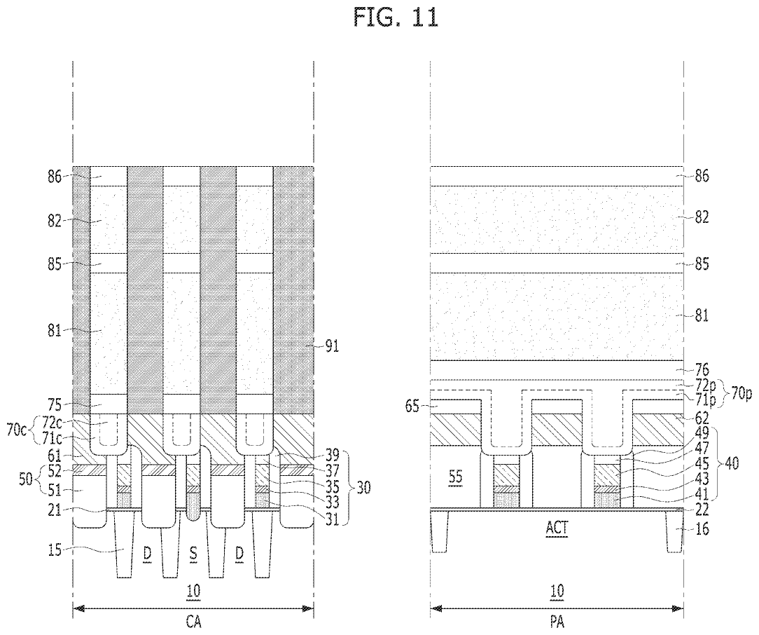

Referring to FIG. 11, the method may include forming storage electrodes 91 in the cell area CA. The storage electrodes 91 may be vertically aligned with or electrically connected to the landing pads 61. The storage electrodes 91 may include a conductor e.g., an N-type doped silicon, a metal silicide, a metal compound, or a metal. In one embodiment, the storage electrodes 91 may include titanium nitride (TiN).

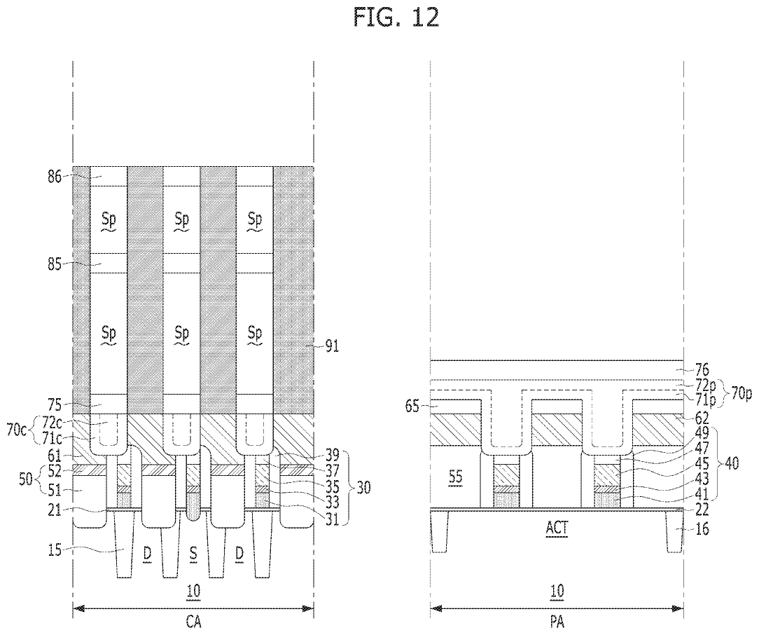

Referring to FIG. 12, the method may further include removing the lower mold insulating layer 81 and the upper mold insulating layer 82. Spaces Sp may be formed by removing the lower mold insulating layer 81 and the upper mold insulating layer 82. The upper supporting pattern 86 and the lower supporting pattern 85 may have holes spatially connecting the spaces Sp.

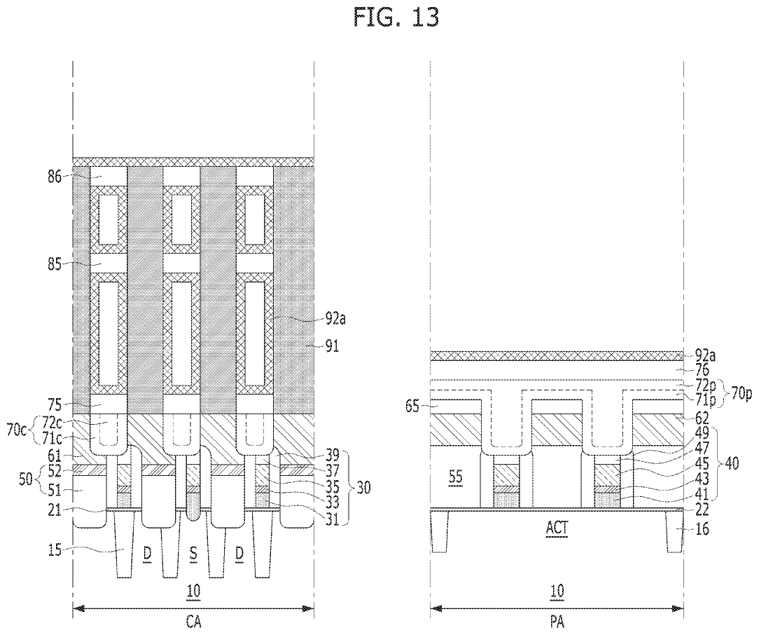

Referring to FIG. 13, the method may further include conformally forming a storage dielectric material layer 92a over the entire surface. The storage dielectric material layer 92a may include a material having a high dielectric constant, e.g., a metal oxide. The storage dielectric material layer 92a may be conformally formed over surfaces of the storage electrodes 91, the lower supporting pattern 85, and the upper supporting pattern 86.

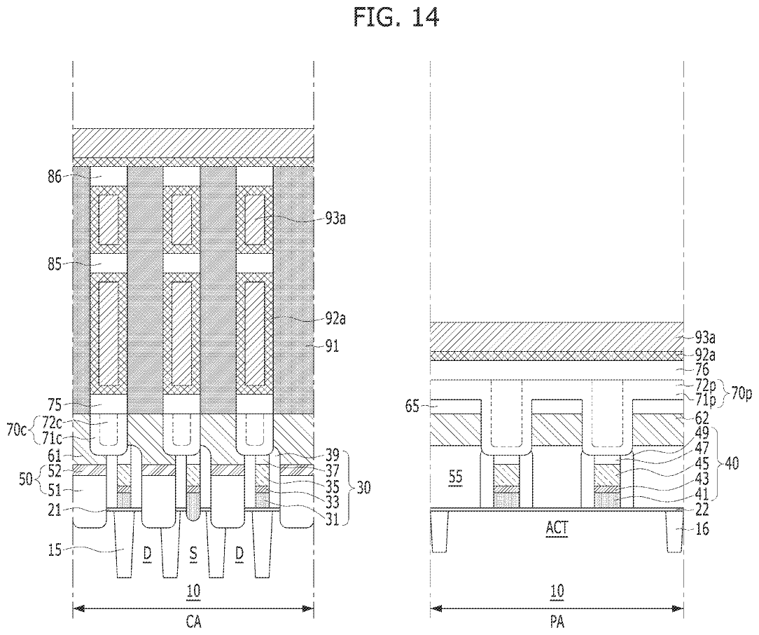

Referring to FIG. 14, the method may include forming a plate electrode material layer 93a over the entire surface. The plate electrode material layer 93a may include a metal or a metal compound. The plate electrode material layer 93a may be conformally formed over a surface of the storage dielectric material layer 92a.

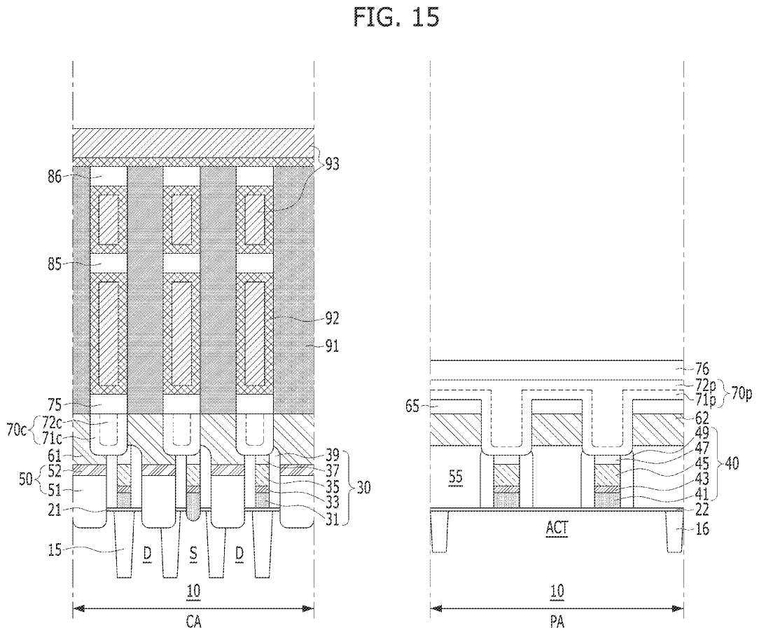

Referring to FIG. 15, the method may further include removing the plate electrode material layer 93a and the storage dielectric material layer 92a in the peripheral area PA to form a storage dielectric layer 92 and plate electrodes 93 in the cell area CA. The plate electrode 93 and the storage dielectric layer 92 may exist only in the cell area CA.

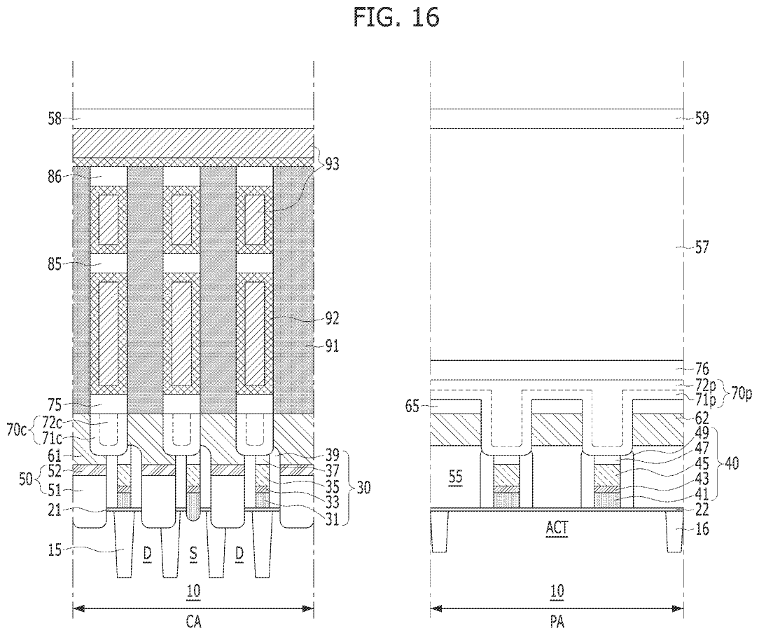

Referring to FIG. 16, the method may further include forming an upper interlayer insulating layer 57 in the peripheral area PA, and forming a cell capping insulating layer 58 in the cell area CA and a peripheral capping insulating layer 59 in the peripheral area PA. The interlayer insulating layer 57 may include silicon oxide (SiO₂), and the cell capping insulating layer 58 and the peripheral capping insulating layer 59 may include silicon nitride (SiN).

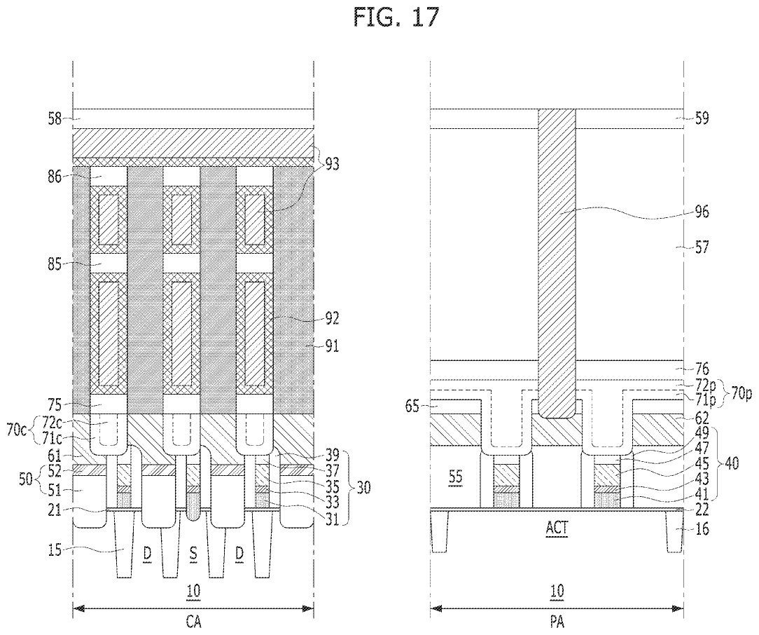

Referring to FIG. 17, the method may further include forming a peripheral via plug 96 vertically passing through the peripheral capping insulating layer 59 and the upper interlayer insulating layer 57 to be connected to one of the conductive peripheral interconnections 62 in the peripheral area PA. The peripheral via plug 96 may include a metal e.g., tungsten (W). Referring back to FIG. 1A, the method may further include forming a plate contact pattern 94 and a plate interconnection pattern 95 connected to the plate electrode 93 in the cell area CA, and forming a peripheral interconnection pattern 97 connected to the peripheral via plug 96 in the peripheral area PA.

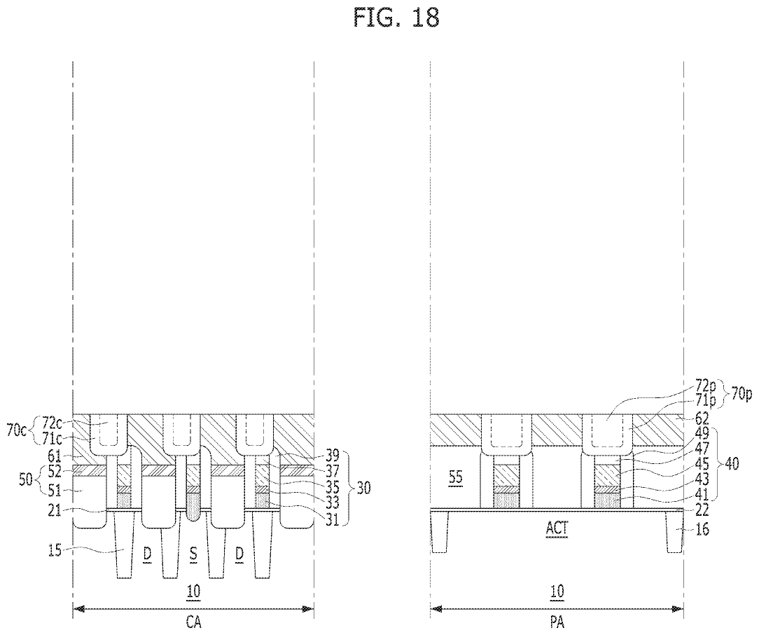

FIG. 18 is a view for describing a method of manufacturing a semiconductor device in accordance with another embodiment of the present disclosure. Referring to FIG. 18, a method of manufacturing a semiconductor device in accordance with one embodiment of the present disclosure may include performing the processes described with reference to FIGS. 3 to 8, and removing the cell spacer layer 70c over top surfaces of the landing pads 61 in the cell area CA and removing the peripheral spacer layer 70p over the peripheral interconnections 62 in the peripheral area PA. In the cell area CA, the top surfaces of the landing pads 61 and top surfaces of the cell spacer layers 70c may be coplanar. In the peripheral area PA, top surfaces of the peripheral interconnections 62 and top surfaces of the peripheral spacer layers 70p may be coplanar. Thereafter, the method may further include performing the processes described with reference to FIGS. 10 to 17, and forming the plate contact pattern 94 and the plate interconnection pattern 95 connected to the plate electrode 93 in the cell area CA and forming the peripheral interconnection pattern 97 connected to the peripheral via plug 96 in the peripheral area PA with further reference to FIG. 1B.

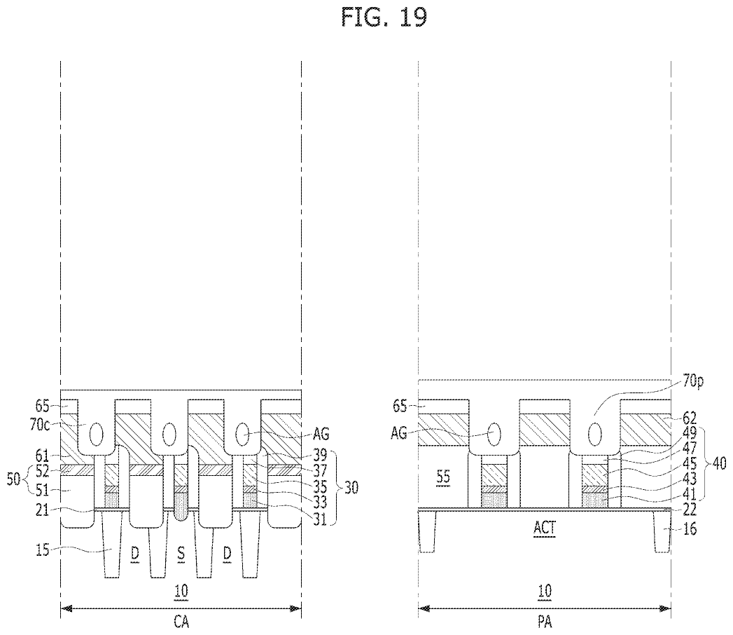

FIG. 19 is a view for describing a method of manufacturing a semiconductor device in accordance with still another embodiment of the present disclosure. Referring to FIG. 19, a method of manufacturing a semiconductor device in accordance with one embodiment of the present disclosure may include performing the processes described with reference to FIGS. 3 to 6, and forming the spacer layers 70c and 70p in the recesses R1 and R2. The spacer layers 70c and 70p may include silicon carbon oxide (SiCO). Air gaps AG may be formed in the recesses R1 and R2. Thereafter, the method may include performing the processes described with reference to FIGS. 9 to 17, and forming the plate contact pattern 94 and the plate interconnection pattern 95 connected to the plate electrode 93 in the cell area CA and forming the peripheral interconnection pattern 97 connected to the peripheral via plug 96 in the peripheral area PA with further reference to FIG. 2A.

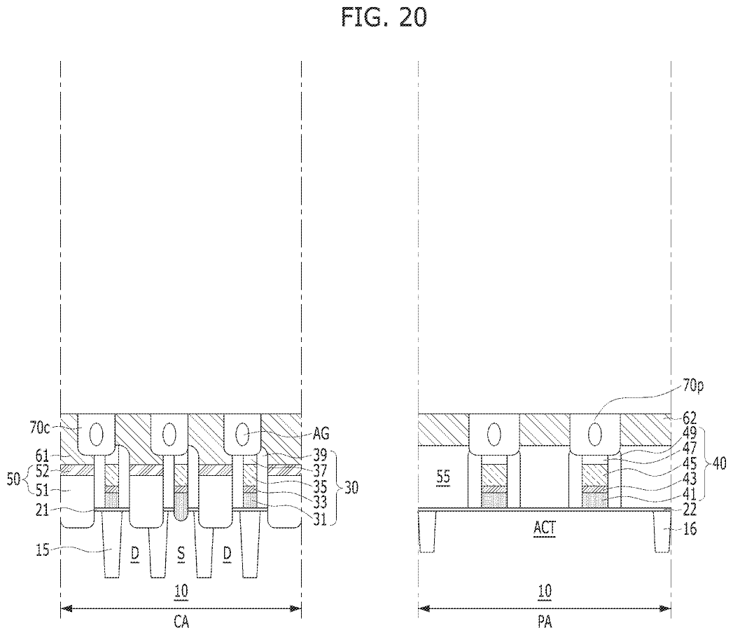

FIG. 20 is a view for describing a method of manufacturing a semiconductor device in accordance with yet another embodiment of the present disclosure. Referring to FIG. 20, the method of manufacturing a semiconductor device in accordance with one embodiment of the present disclosure may include performing the processes described with reference to FIGS. 3 to 6 and 19, and removing the cell spacer layer 70c over the top surfaces of the landing pads 61 in the cell area CA and removing the peripheral spacer layer 70p over the peripheral interconnections 62 in the peripheral area PA. In the cell area CA, the top surfaces of the landing pads 61 and the top surfaces of the cell spacer layers 70c may be coplanar. In the peripheral area PA, the top surfaces of the peripheral interconnections 62 and the top surfaces of the peripheral spacer layers 70p may be coplanar. Thereafter, the method may further include performing the processes described with reference to FIGS. 9 to 17, and forming the plate contact pattern 94 and the plate interconnection pattern 95 connected to the plate electrode 93 in the cell area CA and forming the peripheral interconnection pattern 97 connected to the peripheral via plug 96 in the peripheral area PA with further reference to FIG. 2B.

In accordance with the embodiments of the disclosure, the dielectric constant of the insulating layers between the conductive patterns can be lowered. Accordingly, signal delay and signal loss can be reduced.

Because the insulating layers having a low-k dielectric material include at least two insulating layers having different boron (B) concentrations, the dielectric constant of the insulating layers can be lowered and an etching resistance of the insulating layers can be improved.

While the present invention has been described with respect to the specific embodiments, it will be apparent to those skilled in the art that various changes and modifications may be made without departing from the spirit and scope of the invention disclosed herein.

What is claimed is:

1. A semiconductor device comprising:
a substrate having a cell area and a peripheral area;
transistors in the peripheral area over the substrate;
a lower interlayer insulating layer between the transistors;
interconnections and a first spacer layer over the transistors and the lower interlayer insulating layer, wherein the first spacer layer is disposed between the interconnections; and
an upper interlayer insulating layer over the interconnections and the first spacer layer,
wherein the first spacer layer includes a first lower spacer layer and a first upper spacer layer over the first lower spacer layer,
wherein the first lower spacer layer and the first upper spacer layer include elements of silicon, boron, and nitrogen, and
wherein a boron concentration of the first lower spacer layer is different from a boron concentration of the first upper spacer layer.

2. The semiconductor device of claim 1,
wherein the boron concentration of the first lower spacer layer is higher than the boron concentration of the first upper spacer layer.

3. The semiconductor device of claim 1,
wherein the first lower spacer layer surrounds a bottom surface and side surfaces of the first upper spacer layer in a U-shape.

4. The semiconductor device of claim 1,
wherein the first upper space layer further includes carbon.

5. The semiconductor device of claim 4,
wherein the first lower space layer further includes carbon, and
wherein a carbon concentration of the first upper spacer layer is higher than a carbon concentration of the first lower spacer layer.

6. The semiconductor device of claim 1,
wherein top surfaces of the interconnections and a top surface of the first spacer layer are coplanar.

7. The semiconductor device of claim 1, further comprising:
an etch stop layer over the first spacer layer, and
wherein the first spacer layer includes silicon nitride to have an etch selectivity with respect to the first spacer layer.

8. The semiconductor device of claim 1, further comprising:
hard mask patterns including silicon nitride over the interconnections, and
wherein the first spacer layer extends onto the hard mask patterns.

9. The semiconductor device of claim 1, further comprising:
bit line structures in the cell area over the substrate;
storage contacts between the bit line structures;
landing pads over the storage contacts;
a second spacer layer between the landing pads; and
storage structures over the landing pads,
wherein the second spacer layer includes a second lowerspacer layer and a second upper spacer layer over the second lower spacer layer,
wherein the second lower spacer layer and the second upper spacer layer include the elements of silicon, boron, and nitrogen, and
wherein a boron concentration of the second lower spacer layer is different from a boron concentration of the second upper spacer layer.

10. The semiconductor device of claim 9,
wherein the second lower spacer layer surrounds a bottom surface and side surfaces of the second upper spacer layer in a U-shape.

11. The semiconductor device of claim 9,
wherein the second upper spacer layer further includes carbon.

12. The semiconductor device of claim 11,
wherein the second lower spacer layer further includes carbon, and
wherein a carbon concentration of the second upper spacer layer is higher than a carbon concentration of the second lower spacer layer.

13. The semiconductor device of claim 9,
wherein top surfaces of the landing pads and a top surface of the second spacer layer are coplanar.

14. The semiconductor device of claim 9,
wherein the bit line structures and the transistors are formed at a first same level, and
wherein the interconnections, the first spacer layer, the landing pads, and the second spacer layer are formed at a second same level.

15. A semiconductor device comprising:
a substrate;
transistors over the substrate;
a lower interlayer insulating layer between the transistors;
interconnections and a first spacer layer over the transistors and the lower interlayer insulating layers, wherein the first spacers are disposed between the interconnections; and
an upper interlayer insulating layer over the interconnections and the first spacer layer,
wherein the first spacer layer includes elements of silicon, boron, and nitrogen, and
wherein the first spacer layer has a concentration gradient between a first region having a higher boron concentration and a second region having a lower boron concentration.

16. A semiconductor device comprising,
a substrate having a cell area and a peripheral area;
transistors in the peripheral area over the substrate;
a lower interlayer insulating layer between the transistors;
interconnections and a first spacer layer over the transistors and the lower interlayer insulating layer, wherein the first spacer layer is disposed between the interconnections; and
an upper interlayer insulating layer over the interconnections and the first spacer layer,
wherein the first spacer layer includes a first silicon carbon oxide dielectric, and
wherein the first spacer has an air gap.

17. The semiconductor device of claim 16, further comprising:
an etch stop layer over the first spacer layer, and
wherein the etch stop layer includes silicon nitride to have an etch selectivity with respect to the first spacer layer.

18. The semiconductor device of claim 16, further comprising:
hard mask patterns over the interconnections,
wherein the hard mask patterns include silicon nitride, and
wherein the first spacer layer extends onto the hard mask patterns.

19. The semiconductor device of claim 16, further comprising:
bit line structures in the cell area over the substrate;
storage contacts between the bit line structures;
landing pads over the storage contacts;
a second spacer layer between the landing pads; and
storage structures over the landing pads,
wherein the second spacer layer includes a second silicon carbon oxide dielectric, and
wherein the second spacer layer has an air gap.

20. The semiconductor device of claim 19,
wherein top surfaces of the landing pads and a top surface of the second spacer layer are coplanar.
